(19) United States
(12) Patent Application Publication
(10) Pub. No.: US 2017/0287816 A1
(43) Pub. Date: Oct. 5, 2017

(54) LEADFRAME TOP-HAT MULTI-CHIP SOLUTION

(71) Applicant: Intel Corporation, Santa Clara, CA (US)

(72) Inventor: GERRIT J. VREMAN, Folsom, CA (US)

(73) Assignee: Intel Corporation, Santa Clara, CA (US)

(21) Appl. No.: 15/089,244

(22) Filed: Apr. 1, 2016

(51) Int. Cl. H01L 23/495

(52) U.S. Cl. CPC H01L 23/49513; H01L 23/4952; H01L 23/49548

(57) ABSTRACT

A semiconductor package may include an electrically conductive leadframe having a aperture extending from an upper surface of the leadframe to the lower surface of the leadframe. A wirebond die may be attached or affixed to the upper surface of the leadframe in a location that at least partially obstructs the aperture. A flip-chip die may be disposed proximate the bottom surface of the leadframe at least partially in the aperture. The flip-chip die may be physically coupled to the wirebond die, the leadframe, or both. A mold compound that exposes the lands on the leadframe and the solder bumps or balls on the flip-chip die may at least partially encapsulate the semiconductor package.

### TECHNICAL FIELD

The present disclosure relates to semiconductor packaging.

### BACKGROUND

The top surface of a printed circuit board is considered prime real estate for positioning surface mount components. The number of components, geometries, and terminal connections, when coupled with process capability, drive the level of optimization. If a stand-alone Quad Flat No-Lead (QFN) semiconductor package is positioned on the circuit board, a large area under the package die is an oversize ground pin or ground paddle—a byproduct of the support required for the silicon during package assembly.

The overall printed circuit board area required to position two surface mount components is the sum of the areas occupied by each of the components plus any intervening space required between the components. Consolidating device footprints may be accomplished using a laminate or buildup such as an interposer substrate that is designed to support the die and wirebond aspect in a stacked format. However, such structures are relatively costly.

### BRIEF DESCRIPTION OF THE DRAWINGS

Features and advantages of various embodiments of the claimed subject matter will become apparent as the following Detailed Description proceeds, and upon reference to the Drawings, wherein like numerals designate like parts, and in which:

FIG. 1A provides a perspective view of an illustrative Quad Flat No Lead (QFN) package depicting an illustrative aperture formed in a ground paddle, in accordance with at least one embodiment of the present disclosure;

FIG. 1B provides a plan view of an illustrative printed circuit board depicting the footprint of a QFN package having the illustrative aperture formed in the ground paddle, in accordance with at least one embodiment of the present disclosure;

FIG. 2 provides a cross-sectional elevation of an illustrative semiconductor package in which a flip-chip die contacts a lower surface of a leadframe and a wirebond die contacts an upper surface of the leadframe, in accordance with at least one embodiment of the current disclosure;

FIG. 3 provides a lower perspective view of an illustrative leadframe that includes an aperture in the ground plane to accommodate the insertion of a flip-chip die, in accordance with at least one embodiment of the present disclosure;

FIG. 4 provides a lower perspective view of an illustrative semiconductor package incorporating a flip-chip die coupled to a bottom surface of a leadframe and a wirebond die coupled to an upper surface of the top-hat leadframe such as that depicted in FIG. 3, in accordance with at least one embodiment of the present disclosure;

FIG. 5 provides an upper perspective view of an illustrative wirebond die positioned on an upper surface of an illustrative leadframe such as that depicted in FIG. 3 (wirebonds omitted for clarity), in accordance with at least one embodiment of the present disclosure;

FIG. 6 provides a lower perspective view of an illustrative flip-chip die disposed proximate a lower surface of an illustrative leadframe such as that depicted in FIG. 3, in accordance with at least one embodiment of the present disclosure;

FIG. 7 provides a high-level flow diagram of an illustrative method of semiconductor packaging using a leadframe such as that described in FIG. 3, in accordance with at least one embodiment of the present disclosure; and

FIG. 8 provides high-level flow diagram of an illustrative method of semiconductor packaging that may be used in conjunction with the method described in FIG. 7, in accordance with at least one embodiment of the present disclosure.

Although the following Detailed Description will proceed with reference being made to illustrative embodiments, many alternatives, modifications and variations thereof will be apparent to those skilled in the art.

### DETAILED DESCRIPTION

The systems and methods disclosed herein provide a solution in which the footprint of a flip-chip die is combined into the footprint of a wirebond die to reduce the overall required mounting area of the components. In particular, the systems and methods described herein make use of a strategic use of leadframe etch capability in which at least a portion of the ground plane has been removed to accommodate the insertion of a flip-chip die into the lower surface of the leadframe. A wirebond die may be disposed on the upper surface of the leadframe. The flip-chip die and/or the leadframe may provide support for the wirebond die mounted on the upper surface of the leadframe. The leadframe may then be used during assembly of the semiconductor package to apply the wirebond die to the upper surface of the leadframe and re-run through the die attach flow to apply the flip-chip die on the bottom surface of the leadframe.

Removal of a portion of the ground paddle or ground pin found in the center portion of a leadframe is a matter of design and layout of the leadframe. Such removal may occur, for example by stamping or etching. Removal of a portion of the center paddle has no impact on the cost of the leadframe and selective half etching mask design enables mold compound flow to enter the bottom side die region beneath the wireframe. Beneficially, the systems and methods disclosed herein do not require an additional substrate interposed between the wirebond die and the printed circuit board on which the package is mounted.

As used herein, the terms “upper,” “lower,” “top,” “bottom,” “up,” “down,” “upward,” “downward,” “upwardly,” “downwardly” and similar directional terms should be understood in their relative and not absolute sense. Thus, a component described as being positioned on an “upper surface” of a structure may be considered positioned on a “lateral surface” of the structure if the structure is rotated 90° and positioned on a “lower surface” of the structure if the structure is rotated 180°. Such implementations should be considered as included within the scope of the present disclosure.

A surface-mount semiconductor package is provided. The surface mount semiconductor package may include a leadframe having an upper surface and a lower surface, wherein a portion of a ground paddle portion of the leadframe has been removed to provide an aperture that extends from the upper surface to the lower surface of the leadframe; and a flip-chip die positioned proximate the leadframe such that the flip-chip die obstructs at least a portion of the aperture through the leadframe.

A leadframe semiconductor packaging method is also provided. The method may include disposing a lower surface of a wirebond die adjacent an upper surface of an electrically conductive leadframe, the wirebond die positioned proximate an aperture extending from the upper surface of the leadframe to a lower surface of the leadframe and coupling an upper surface of a flip-chip die to the lower surface of the wirebond die, the flip-chip die positioned in at least a portion of the aperture.

An electrical device is provided. The electrical device may include a printed circuit board and a surface mount semiconductor package that includes:

a leadframe electrically conductively coupled to the printed circuit board, the leadframe having an upper surface and a lower surface, wherein a portion of a ground paddle portion of the leadframe has been removed to provide a central aperture that extends from the upper surface to the lower surface of the leadframe; a flip-chip die electrically conductively coupled to the printed circuit board, the flip-chip die positioned proximate the leadframe such that the flip-chip die obstructs at least a portion of the central aperture through the leadframe; and a wirebond die electrically conductively coupled to the leadframe via a plurality of conductors, the wirebond die affixed to the upper surface of the leadframe, opposite the flip-chip die.

A leadframe surface-mount semiconductor system is provided. The system may include a means for disposing a lower surface of a wirebond die adjacent an upper surface of an electrically conductive leadframe, the wirebond die positioned proximate an aperture extending from the upper surface of the leadframe to a lower surface of the leadframe; and a means for coupling an upper surface of a flip-chip die to the lower surface of the wirebond die, the flip-chip die positioned in at least a portion of the aperture.

A leadframe device is also provided. The leadframe may include an electrically conductive member having an exterior perimeter, an upper surface, a lower surface, and at least one aperture extending from the upper surface of the electrically conductive member to the lower surface of the electrically conductive member; a number of electrical contact surfaces disposed about at least a portion of the exterior perimeter of the electrically conductive member; a first area disposed on at least a portion of the lower surface of the electrically conductive member, the first area to accommodate an attachment of a flip-chip die; and a second area disposed on at least a portion of the upper surface of the electrically conductive member, the second area to accommodate an attachment of a wirebond die.

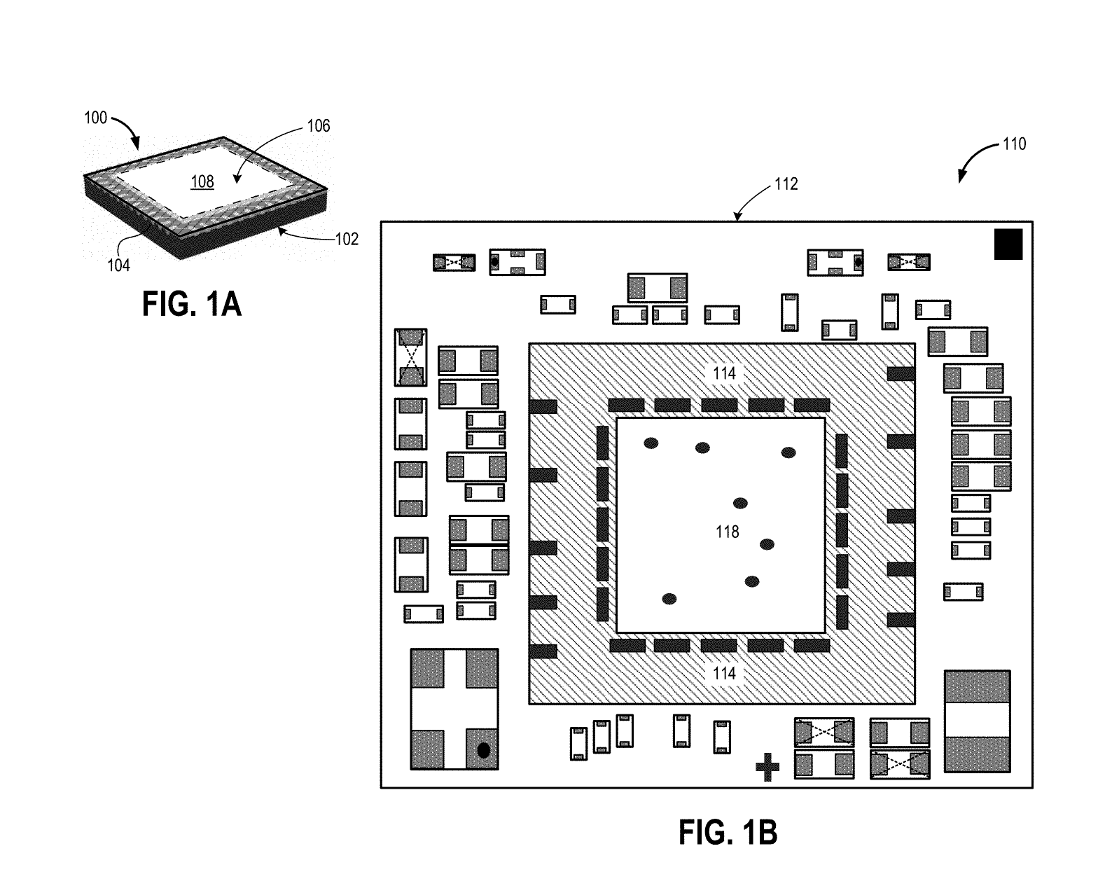

FIG. 1A provides a perspective view of an illustrative Quad Flat No Lead (QFN) package 102 depicting an illustrative ground paddle cutout 108, in accordance with at least one embodiment of the present disclosure. A typical QFN package 102 is a near chip scale plastic encapsulated package that includes a leadframe substrate. The package 102 includes a number of perimeter lands 104 that extend along all four sides of the package 102 (hence the presence of the term “quad” in the name of the package). The leadframe substrate may include one or more electrically conductive materials, metals, and/or metal alloys, such as copper and copper-containing alloys. A mold compound may encapsulate the wirebond die and the leadframe with the exception of the lands 104 and the centrally located ground pin or ground paddle 106.

In embodiments, a number of apertures 108 may be removed from all or a portion of the ground paddle 106. Each aperture 108 may completely penetrate the leadframe, extending from the lower surface of the leadframe to the upper surface of the leadframe. As depicted in FIG. 1A, in some embodiments, only a single aperture 108 may be formed in the ground paddle 106. In some instances, the aperture 108 in the leadframe may be the same size as the flip-chip die, or may be smaller in area or larger in area than the flip-chip die. In other instances, the aperture 108 in the leadframe may be the same size as the wirebond die, or may be smaller in area or larger in area than the wirebond die. Each of the number of apertures 108 may be formed using any current or future available material removal technology capable of removing material from the leadframe. Example material removal technologies include, but are not limited to, stamping, punching, die-cutting, or etching. Beneficially, forming the aperture 108 in the leadframe is has no impact on the cost of the leadframe 202. Further, the use of a leadframe 202 between the wirebond die 220 and the flip-chip die 210 does not require the use of an additional substrate between the wirebond die 220 and the printed circuit board 110, potentially improving the performance of the semiconductor package 100.

FIG. 1B provides a plan view of an illustrative printed circuit board 110 depicting the area 114 occupied by a QFN package 102 having an illustrative aperture 108 formed in the ground paddle 106, in accordance with at least one embodiment of the present disclosure. As depicted in FIG. 1B, the area 114 occupied by the QFN package 102 is shown as a hatched region. The area 118 of the QFN footprint 114 freed by the aperture 108 in the ground paddle 106 is shown as an unhatched region within the area 114 occupied by the QFN package. In the illustrative example depicted in FIG. 1B, the collocation of the flip-chip die within the footprint of the leadframe coupled to the wirebond die permits the coupling of both dies to the printed circuit board 110. Given the size constraints of the printed circuit board 110 in FIG. 1B, insufficient space exists for separate coupling of the flip-chip die and the wirebond die to the circuit board. Thus, in circumstances such as those depicted in FIG. 1B, the use of a leadframe having an aperture 108 formed in the ground paddle 106 to accommodate the flip-chip die beneficially permits the use of a smaller printed circuit board.

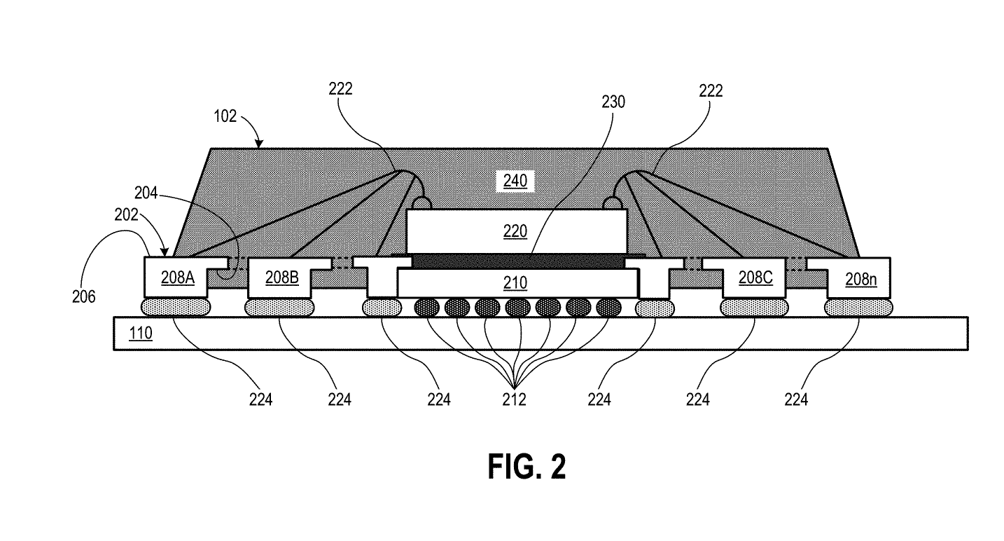

FIG. 2 is a cross-sectional elevation of an illustrative semiconductor package in which a flip-chip die 210 contacts a lower surface of a leadframe and a wirebond die 220 contacts an upper surface of the leadframe, in accordance with at least one embodiment of the current disclosure. As depicted in FIG. 2, a leadframe 202 having an upper surface 204 and a lower surface 206 is disposed between a flip-chip chip scale package (CSP) die 210 and a wirebond die 220. In some implementations, a die attach 230 may be disposed in the aperture 108 between all or a portion of the flip-chip die 210 and the wirebond die 220. In embodiments, a mold compound 240 may partially or completely encapsulate the flip-chip die 210, the leadframe 202 and the wirebond die 220.

The leadframe 202 is formed from an electrically conductive material, such as copper or a copper alloy, and includes an upper surface 204 and a lower surface 206. In embodiments, all or a portion of the lower surface 206 may be etched or otherwise patterned to form a number of lands 208A-208n (collectively, “lands 208”) that project from the lower surface 206 of the leadframe 202. In embodiments, some or all of the lands 208 may slightly project from or be flush with the exterior surfaces of the mold compound 240 forming the packaging about the wirebond die 220, leadframe 202, and the flip-chip die 210. For example, in some implementations, all or a portion of the bottom surface 204 of the leadframe 202 may be etched to create the lands 208. Solder connections 224 may electrically conductively couple and physically affix the lands 208 to the substrate 110.

The flip-chip die 210 includes an upper surface that may be positioned near or proximate the lower surface 204 of the leadframe 202 and a lower surface to which a number of solder balls or solder bumps 212 may be attached. The upper surface of the flip-chip die 210 is positioned proximate at least a portion of the lower surface 204 of the leadframe 202. In embodiments, at least a portion of the flip-chip die 210 may be disposed in at least a portion of the aperture 108 formed in the leadframe 202. The solder balls or solder bumps 212 affixed to the flip-chip die 210 may protrude from the bottom of the semiconductor package, thereby enabling the physical and conductive coupling of the flip-chip die 210 to the underlying printed circuit board substrate 110.

The wirebond die 220 includes a lower surface that may be positioned near or proximate the upper surface 206 of the leadframe 202. A number of wirebonds 222 electrically conductively couple the wirebond die 220 to at least some of the lands 208 on the leadframe 202. In some implementations, the wirebond die 220 may include a single wirebond die. In other implementations, the wirebond die 220 may include a number of stacked wirebond dies.

In embodiments, the wirebond die 220 may have a physical size or configuration that prevents the die from passing through the aperture 108 in the leadframe 202. In such embodiments, the wirebond die 220 may provide a stable attachment point for the flip-chip die 210. A die attach 230 may be disposed between the wirebond die 220 and the flip-chip die 210. Such die attach 230 may include any current or future substance or material suitable for affixing the wirebond die 220 and the flip-chip die 210 to each other and/or to the leadframe 202. Example die attach materials include, but are not limited to, a tape die attach and an epoxy die attach.

In embodiments, a mold compound 240 may encapsulate the wirebond die 220, encapsulate at least a portion of the leadframe 202, and encapsulate at least a portion of the flip-chip die 210. In embodiments, the bottom surface 204 of the leadframe 202 may be ½ etched to facilitate the flow of mold compound 240 beneath the leadframe 202 and around the flip-chip die 210.

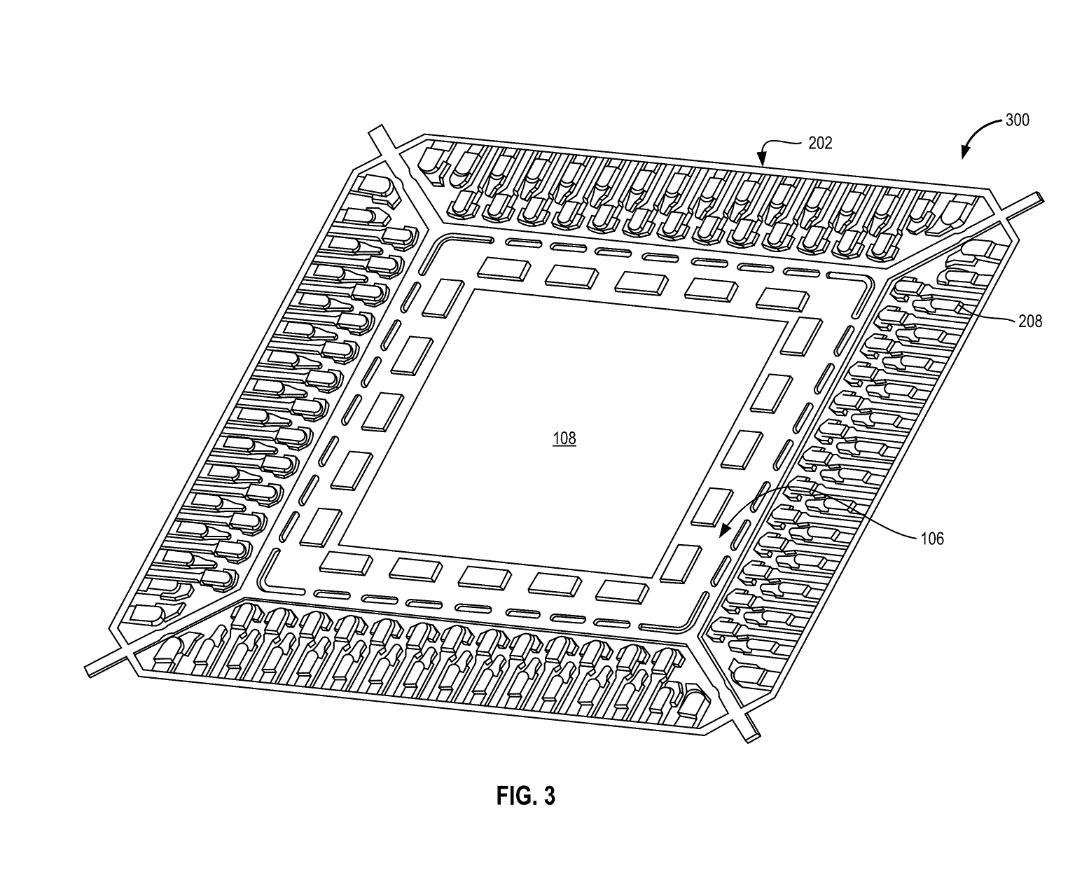

FIG. 3 provides a lower perspective view of an illustrative leadframe 300 that includes an aperture 108 in the ground plane 106 to accommodate the placement of a flip-chip die 210, in accordance with at least one embodiment of the present disclosure. Although depicted and described in terms of a Quad Flat No-Lead (“QFN”) package, the systems and methods described herein are applicable to other package types, for example Quad Flat Packages (“QFP”), embodiments of which should be considered as included within the scope of this disclosure.

As depicted in FIG. 3, the leadframe 300 may include a single aperture 108 formed in the ground plane 106. In embodiments, the aperture 108 may include a single aperture. In other embodiments, the aperture 108 may include a plurality of apertures 108A-108n. The aperture 108 may have any dimensions. The leadframe 300 may include any number of lands 208 disposed about all or a portion of the perimeter of the leadframe 300. In some implementations, the leadframe 300 may include a number of rows of lands 208 disposed about all or a portion of the perimeter of leadframe 300.

In some implementations, one or more dimensions of the aperture 108 may be determined, at least in part, on the dimensions of the wirebond die 220 such that one or more dimensions of the aperture 108 are less than the corresponding dimension of the aperture 108. Such would permit the leadframe 300 to provide a degree of physical support the wirebond die 220 and would permit the use and attachment of any size flip-chip die 210 to the lower surface of the wirebond die 220.

In some implementations, one or more dimensions of the aperture 108 may be determined, at least in part, on the dimensions of the flip-chip die 210. In such instances, the bottom surface 204 of the leadframe 300 may be half-etched about the aperture 108 such that the dimensions of the half-etched area are similar to the dimensions of the flip-chip die 210. Such would permit the leadframe 300 to provide a degree of physical support to the flip-chip die 210 and would permit the use of any size wirebond die 220 on the top surface of the flip-chip die 210.

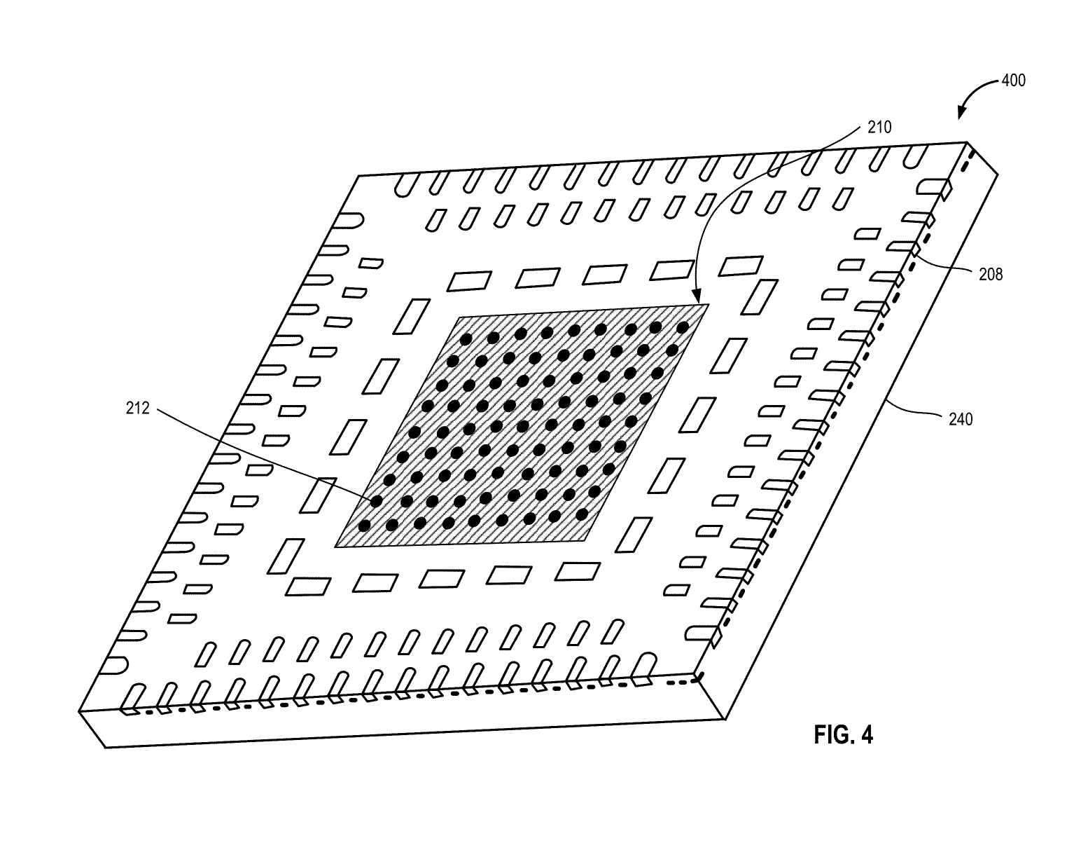

FIG. 4 provides a lower perspective view of an illustrative semiconductor package 400 incorporating a flip-chip die 210 coupled to a lower surface 204 of a leadframe 300, such as that depicted in FIG. 3, and a wirebond die 220 coupled to an upper surface 206 of the leadframe 300, in accordance with at least one embodiment of the present disclosure. As depicted in FIG. 4, a mold compound 240 has been disposed about the wirebond die 220, the leadframe 300, and the flip-chip die 210, leaving only the lands 208 of the leadframe 300 and the bottom surface of the flip-chip die 210 exposed. The semiconductor package 400 may be physically and conductively coupled to a printed circuit board substrate 100 using the solder bumps 212 or balls on the flip-chip die 210 and solder connections between some or all of the lands 208 and the printed circuit board substrate 100.

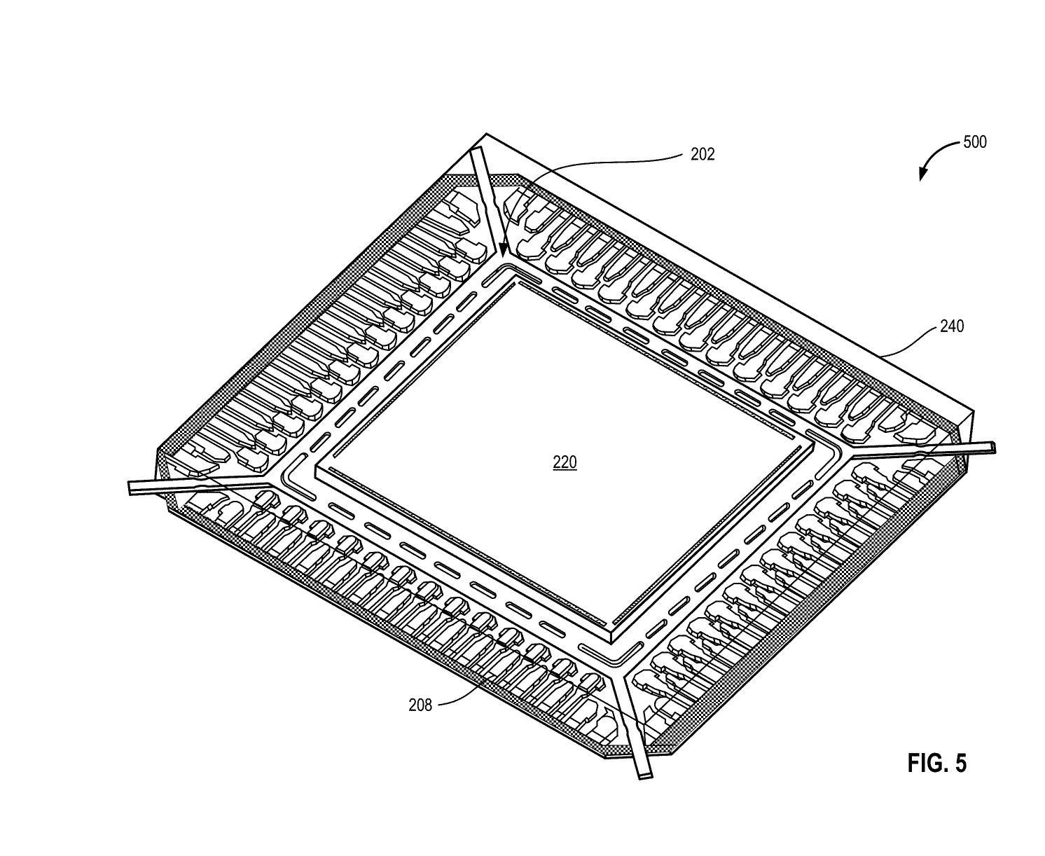

FIG. 5 provides an upper perspective view of an illustrative semiconductor package 500 that includes a wirebond die 220 positioned on an upper surface 206 of an illustrative leadframe 300 such as that depicted in FIG. 3 (wirebonds omitted for clarity), in accordance with at least one embodiment of the present disclosure. As depicted in FIG. 5, the wirebond die 220 is disposed proximate the aperture 108 in the leadframe 300. Although not depicted in FIG. 5 for clarity, wirebonds 222 electrically conductively couple pads on the wirebond die 220 to some or all of the lands 208 on the leadframe 300. The semiconductor package 500 includes a mold compound 240 encapsulating the wirebond die 220, at least partially encapsulating the leadframe 300, and at least partially encapsulating the flip-chip die 210.

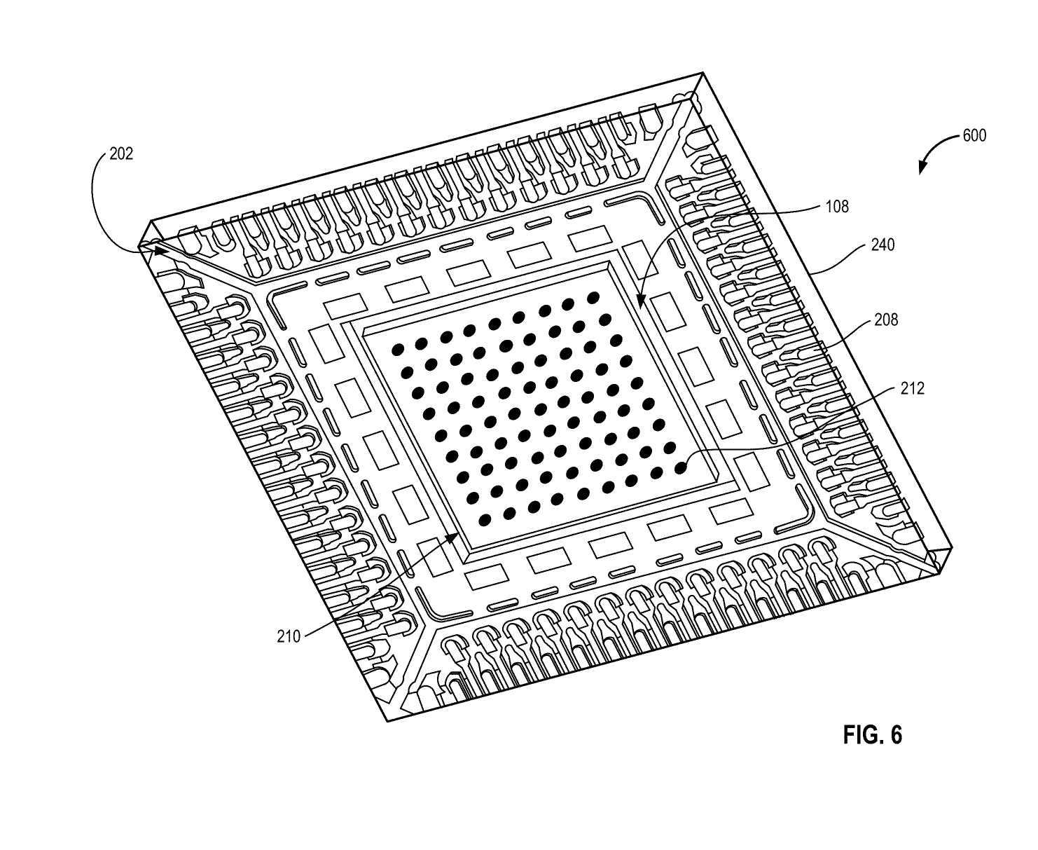

FIG. 6 provides a lower perspective view of an illustrative semiconductor package 500 that includes a flip-chip die 210 disposed proximate a lower surface 204 of an illustrative leadframe 300 such as that depicted in FIG. 3, in accordance with at least one embodiment of the present disclosure. As depicted in FIG. 6, a flip-chip die 210 having physical dimensions smaller than the aperture 108 may be disposed within the aperture 108. In such instances, a tape or epoxy die attach 230 may be used to physically bond or affix the flip-chip die 210 to the bottom of the wirebond die 220 attached to the upper surface 206 of the leadframe 300. In embodiments, some or all of the lands 208 may extend from the bottom of the semiconductor package 500. In other embodiments, some or all of the lands 208 may be flush with the bottom of the semiconductor package. Visible in FIG. 6 are the solder bumps or solder balls 212 affixed to the lower surface of the flip chip die 210.

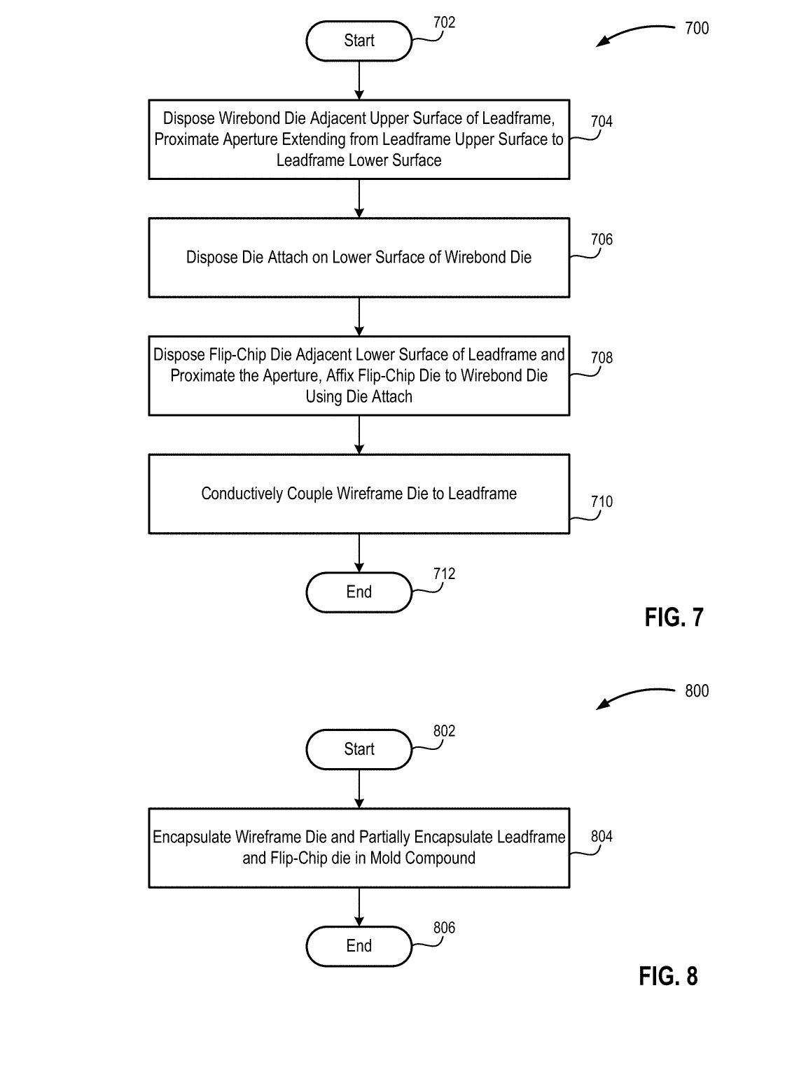

FIG. 7 provides a high-level flow diagram of an illustrative method 700 of semiconductor packaging using a leadframe 300 such as that described in FIG. 3, in accordance with at least one embodiment of the present disclosure. The method commences at 702.

At 704, a wirebond die 220 may be disposed proximate an upper surface 206 of a leadframe 300. The wirebond die 220 may be positioned relative to an aperture 108 extending from the upper surface 206 of the leadframe 300 to a lower surface 204 of the leadframe 300 such that the wirebond die 220 at least partially obstructs the aperture 108.

At 706, the wireframe 300 and wirebond die 220 may be re-run through a die attach 220 flow in preparation for the attachment of the flip-chip die 210 to the bottom surface of the wirebond die 230. The die attach 220 may include, but is not limited to a tope die attach or an epoxy die attach.

At 708, a flip-chip die 210 may be disposed in whole or in part within all or a portion of the aperture 108 and proximate at least a portion of the lower surface of the wirebond die 220.

At 710, some or all of the contacts or pads on the wirebond die 220 may be conductively coupled via wirebonds 222 to at least some of the lands 208 on the wireframe 300. The method 700 concludes at 712.

FIG. 8 provides high-level flow diagram of an illustrative method 800 of semiconductor packaging that may be used in conjunction with the method described in FIG. 7, in accordance with at least one embodiment of the present disclosure. In at least some implementations, the wirebond die 220, leadframe 300, and flip-chip die 210 package generated by the method 700 may be at least partially encapsulated in a mold compound 240. The method 800 commences at 802.

At 804 a mold compound 240 is disposed about the wirebond die 220, at least a portion of the wireframe 300, and at least a portion of the flip-chip die 210. In some implementations, the half-etching of the leadframe 300 may advantageously permit the flow of mold compound 240 along the lower surface 204 of the leadframe 204. The method 800 concludes at 806.

Additionally, operations for the embodiments have been further described with reference to the above figures and accompanying examples. Some of the figures may include a logic flow. Although such figures presented herein may include a particular logic flow, it can be appreciated that the logic flow merely provides an example of how the general functionality described herein can be implemented. Further, the given logic flow does not necessarily have to be executed in the order presented unless otherwise indicated. In addition, the given logic flow may be implemented by a hardware element, a software element executed by a processor, or any combination thereof. The embodiments are not limited to this context.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications. Thus, the breadth and scope of the present invention should not be limited by any of the above-described exemplary embodiments, but should be defined only in accordance with the following claims and their equivalents.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

Reference throughout this specification to “one embodiment” or “an embodiment” means that a particular feature, structure, or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The following examples pertain to further embodiments. The following examples of the present disclosure may comprise subject material such as a device, a method, means for performing acts based on the method and/or a system for providing a semiconductor package containing at least one wirebond die 220, at least one leadframe 300, and at least one flip-chip die 210.

According to example 1, there is provided a surface-mount semiconductor package. The surface mount semiconductor package may include a leadframe having an upper surface and a lower surface, wherein a portion of a ground paddle portion of the leadframe has been removed to provide an aperture that extends from the upper surface to the lower surface of the leadframe; and a flip-chip die positioned proximate the leadframe such that the flip-chip die obstructs at least a portion of the aperture through the leadframe.

Example 2 may include elements of example 1 and may additionally include a wirebond die affixed to the upper surface of the leadframe, opposite the flip-chip die.

Example 3 may include elements of example 2 and may additionally include at least one of: a tape die-attach or an epoxy die attach disposed between the flip-chip die and the wirebond die.

Example 4 may include elements of example 3 where the flip-chip die is affixed to the wirebond die and the wirebond die is affixed to at least a portion of the upper surface of the leadframe.

Example 5 may include elements of example 3 where the flip-chip die is affixed to at least a portion of the lower surface of the leadframe and the wirebond die is affixed to at least a portion of the upper surface of the leadframe.

Example 6 may include elements of example 1 where the lower surface of the leadframe comprises a half-relief etched surface to permit the flow of mold compound beneath the leadframe and flip-chip die when the surface-mount package is attached to a printed circuit board.

Example 7 may include elements of example 1 where the flip-chip die includes a land pad interconnect that includes at least one of: a bare under bump metallurgy (UBM); a semi-ball grid array; or a plated matte tin finish.

According to example 8, there is provided a leadframe semiconductor packaging method. The method may include disposing a lower surface of a wirebond die adjacent an upper surface of an electrically conductive leadframe, the wirebond die positioned proximate an aperture extending from the upper surface of the leadframe to a lower surface of the leadframe and coupling an upper surface of a flip-chip die to the lower surface of the wirebond die, the flip-chip die positioned in at least a portion of the aperture.

Example 9 may include elements of example 8 and may further include conductively coupling a number of pads on the wirebond die to a number of pads on the leadframe using wirebonds.

Example 10 may include elements of example 9 and may additionally include encapsulating the wirebond die, at least a portion of the leadframe, and at least a portion of the flip-chip die in a mold compound.

Example 11 may include elements of example 9 where coupling the flip-chip die to a wirebond die adjacent the upper surface of the leadframe, the wirebond die positioned proximate the aperture may include coupling the flip-chip die to the wirebond die via at least one of: a tape die attach or an epoxy die attach.

Example 12 may include elements of example 9 where disposing an upper surface of an inverted flip-chip die adjacent a lower surface of a leadframe may include disposing an upper surface of an inverted flip-chip die adjacent a lower surface of a leadframe, the lower surface of a ½-etched leadframe.

According to example 13, there is provided an electrical device. The electrical device may include a printed circuit board and a surface mount semiconductor package that includes: a leadframe electrically conductively coupled to the printed circuit board, the leadframe having an upper surface and a lower surface, wherein a portion of a ground paddle portion of the leadframe has been removed to provide a central aperture that extends from the upper surface to the lower surface of the leadframe; a flip-chip die electrically conductively coupled to the printed circuit board, the flip-chip die positioned proximate the leadframe such that the flip-chip die obstructs at least a portion of the central aperture through the leadframe; and a wirebond die electrically conductively coupled to the leadframe via a plurality of conductors, the wirebond die affixed to the upper surface of the leadframe, opposite the flip-chip die.

Example 14 may include elements of example 13, and may additionally include at least one of: a tape die-attach or an epoxy die attach disposed between the flip-chip die and the wirebond die.

Example 15 may include elements of example 14 where the flip-chip die is affixed to the wirebond die and the wirebond die is affixed to at least a portion of the upper surface of the leadframe.

Example 16 may include elements of example 14 where the flip-chip die is affixed to at least a portion of the lower surface of the leadframe and the wirebond die is affixed to at least a portion of the upper surface of the leadframe.

Example 17 may include elements of example 13 where the lower surface of the leadframe comprises a half-relief etched surface to permit the flow of mold compound beneath the leadframe and flip-chip die when the surface-mount package is attached to a printed circuit board.

Example 18 may include elements of example 13 where the flip-chip die includes a land pad interconnect that includes at least one of: a bare under bump metallurgy (UBM); a semi-ball grid array; or a plated matte tin finish.

Example 19 may include elements of example 13 where the semiconductor package further may include a mold compound encapsulating the wirebond die and at least partially encapsulating the leadframe and the flip-chip die.

According to example 20, there is provided a leadframe surface-mount semiconductor system that may include a means for disposing a lower surface of a wirebond die adjacent an upper surface of an electrically conductive leadframe, the wirebond die positioned proximate an aperture extending from the upper surface of the leadframe to a lower surface of the leadframe; and a means for coupling an upper surface of a flip-chip die to the lower surface of the wirebond die, the flip-chip die positioned in at least a portion of the aperture.

Example 21 may include elements of example 20, and may additionally include a means for conductively coupling a number of pads on the wirebond die to a number of pads on the leadframe using wirebonds.

Example 22 may include elements of example 21, and may additionally include a means for encapsulating the wirebond die, at least a portion of the leadframe, and at least a portion of the flip-chip die in a mold compound.

Example 23 may include elements of example 20 where the means for coupling the flip-chip die to a wirebond die adjacent the upper surface of the leadframe, the wirebond die positioned proximate the aperture may include a means for coupling the flip-chip die to the wirebond die via at least one of: a tape die attach or an epoxy die attach.

Example 24 may include elements of example 20 where the means for disposing an upper surface of an inverted flip-chip die adjacent a lower surface of a leadframe may include a means for disposing an upper surface of an inverted flip-chip die adjacent a lower surface of a leadframe, the lower surface of a ½-etched leadframe.

According to example 25, there is provided a leadframe. The leadframe may include an electrically conductive member having an exterior perimeter, an upper surface, a lower surface, and at least one aperture extending from the upper surface of the electrically conductive member to the lower surface of the electrically conductive member; a number of electrical contact surfaces disposed about at least a portion of the exterior perimeter of the electrically conductive member; a first area disposed on at least a portion of the lower surface of the electrically conductive member, the first area to accommodate an attachment of a flip-chip die; and a second area disposed on at least a portion of the upper surface of the electrically conductive member, the second area to accommodate an attachment of a wirebond die.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

1. A surface-mount semiconductor package, comprising:
a leadframe having an upper surface and a lower surface, wherein a portion of a ground paddle portion of the leadframe has been removed to provide an aperture that extends from the upper surface to the lower surface of the leadframe; and
a flip-chip die positioned proximate the leadframe such that the flip-chip die obstructs at least a portion of the aperture through the leadframe.

2. The surface-mount semiconductor package of claim 1, further comprising:
a wirebond die affixed to the upper surface of the leadframe, opposite the flip-chip die.

3. The surface-mount semiconductor package of claim 2, further comprising:
at least one of: a tape die-attach or an epoxy die attach disposed between the flip-chip die and the wirebond die.

4. The surface mount semiconductor package of claim 3 wherein the flip-chip die is affixed to the wirebond die and the wirebond die is affixed to at least a portion of the upper surface of the leadframe.

5. The surface mount semiconductor package of claim 3 wherein the flip-chip die is affixed to at least a portion of the lower surface of the leadframe and the wirebond die is affixed to at least a portion of the upper surface of the leadframe.

6. The surface-mount semiconductor package of claim 1 wherein the lower surface of the leadframe comprises a half-relief etched surface to permit the flow of mold compound beneath the leadframe and flip-chip die when the surface-mount package is attached to a printed circuit board.

7. The surface-mount semiconductor package of claim 1 wherein the flip-chip die includes a land pad interconnect that includes at least one of: a bare under bump metallurgy (UBM); a semi-ball grid array; or a plated matte tin finish.

8. A leadframe semiconductor method, comprising:
disposing a lower surface of a wirebond die adjacent an upper surface of an electrically conductive leadframe, the wirebond die positioned proximate an aperture extending from the upper surface of the leadframe to a lower surface of the leadframe; and
coupling an upper surface of a flip-chip die to the lower surface of the wirebond die, the flip-chip die positioned in at least a portion of the aperture.

9. The leadframe semiconductor method of claim 8, further comprising:
conductively coupling a number of pads on the wirebond die to a number of lands on the leadframe using wirebonds.

10. The leadframe semiconductor method of claim 9, further comprising:
encapsulating the wirebond die, at least a portion of the leadframe, and at least a portion of the flip-chip die in a mold compound.

11. The leadframe semiconductor method of claim 9 wherein coupling the flip-chip die to a wirebond die adjacent the upper surface of the leadframe, the wirebond die positioned proximate the aperture comprises:
coupling the flip-chip die to the wirebond die via at least one of: a tape die attach or an

12. The leadframe semiconductor method of claim 9 wherein disposing an upper surface of an inverted flip-chip die adjacent a lower surface of a leadframe comprises:
disposing an upper surface of an inverted flip-chip die adjacent a lower surface of a leadframe, the lower surface of a ½-etched leadframe.

13. An electrical device, comprising:
a printed circuit board; and
a surface mount semiconductor package, that includes:
a leadframe electrically conductively coupled to the printed circuit board, the leadframe having an upper surface and a lower surface, wherein a portion of a ground paddle portion of the leadframe has been removed to provide a central aperture that extends from the upper surface to the lower surface of the leadframe;
a flip-chip die electrically conductively coupled to the printed circuit board, the flip-chip die positioned proximate the leadframe such that the flip-chip die obstructs at least a portion of the central aperture through the leadframe; and
a wirebond die electrically conductively coupled to the leadframe via a plurality of conductors, the wirebond die affixed to the upper surface of the leadframe, opposite the flip-chip die.

14. The electrical device of claim 13, further comprising:
at least one of: a tape die-attach or an epoxy die attach disposed between the flip-chip die and the wirebond die.

15. The electrical device of claim 14 wherein the flip-chip die is affixed to the wirebond die and the wirebond die is affixed to at least a portion of the upper surface of the leadframe.

16. The electrical device of claim 14 wherein the flip-chip die is affixed to at least a portion of the lower surface of the leadframe and the wirebond die is affixed to at least a portion of the upper surface of the leadframe.

17. The electrical device of claim 13 wherein the lower surface of the leadframe comprises a half-relief etched surface to permit the flow of mold compound beneath the leadframe and flip-chip die when the surface-mount package is attached to a printed circuit board.

18. The electrical device of claim 13 wherein the flip-chip die includes a land pad interconnect that includes at least one of: a bare under bump metallurgy (UBM); a semi-ball grid array; or a plated matte tin finish.

19. The electrical device of claim 13 wherein the top-hat surface mount package further comprises:
a mold compound encapsulating the wirebond die and at least partially encapsulating the leadframe and the flip-chip die.

20. A surface-mount semiconductor system, comprising:
a means for disposing a lower surface of a wirebond die adjacent an upper surface of an electrically conductive leadframe, the wirebond die positioned proximate an aperture extending from the upper surface of the leadframe to a lower surface of the leadframe; and
a means for coupling an upper surface of a flip-chip die to the lower surface of the wirebond die, the flip-chip die positioned in at least a portion of the aperture.

21. The surface-mount semiconductor system of claim 20, further comprising:
a means for conductively coupling a number of pads on the wirebond die to a number of lands on the leadframe using wirebonds.

22. The surface-mount semiconductor system of claim 21, further comprising:
a means for encapsulating the wirebond die, at least a portion of the leadframe, and at least a portion of the flip-chip die in a mold compound.

23. The surface-mount semiconductor system of claim 20 wherein the means for coupling the flip-chip die to a wirebond die adjacent the upper surface of the leadframe, the wirebond die positioned proximate the aperture comprises:
a means for coupling the flip-chip die to the wirebond die via at least one of: a tape die attach or an epoxy die attach.

24. The surface-mount semiconductor system of claim 20 wherein the means for disposing an upper surface of an inverted flip-chip die adjacent a lower surface of a leadframe comprises:
a means for disposing an upper surface of an inverted flip-chip die adjacent a lower surface of a leadframe, the lower surface of a ½-etched leadframe.

25. A leadframe, comprising:
an electrically conductive member having an exterior perimeter, an upper surface, a lower surface, and at least one aperture extending from the upper surface of the electrically conductive member to the lower surface of the electrically conductive member;
a number of electrical contact surfaces disposed about at least a portion of the exterior perimeter of the electrically conductive member;
a first area disposed on at least a portion of the lower surface of the electrically conductive member, the first area to accommodate an attachment of a flip-chip die; and
a second area disposed on at least a portion of the upper surface of the electrically conductive member, the second area to accommodate an attachment of a wirebond die.
